(19) United States
(12) Patent Application Publication
(10) Pub. No.: US 2026/0230735 A1
(43) Pub. Date: Aug. 6, 2026

(54) MOUNTING SYSTEM FOR MODULARLY CONSTRUCTED, ELECTRONICALLY CONTROLLABLE SOUND TRANSDUCER SYSTEMS

(71) Applicant: HOLOPLOT GMBH, Berlin (DE)

(72) Inventor: Klas DALBJORN, Hovås (SE)

(73) Assignee: HOLOPLOT GMBH, Berlin (DE)

(21) Appl. No.: 19/128,774

(22) PCT Filed: Nov. 9, 2023
(86) PCT No.: PCT/EP2023/081281

§ 371 Date: May 9, 2025

(30) Foreign Application Priority Data
Dec. 6, 2022 (DE) 102022132347.1

(51) Int. Cl. H04R 1/02; H04R 1/40; H04R 3/12; H05K 7/20

(52) U.S. Cl. CPC H04R 1/026; H04R 1/025; H04R 1/028; H04R 1/403; H04R 3/12; H05K 7/205; H04R 2201/028; H04R 2201/401; H04R 2203/12

(57) ABSTRACT

The invention relates to a mounting system for modularly constructed, electronically controllable sound transducer systems, characterized by at least one mounting frame (100), in particular a plurality of mounting frames (100), and at least one module insert (200), in particular a plurality of module inserts (200), wherein the at least one mounting frame (100) can be mounted in a fixed location and the at least one module insert (200) with the electronic com-ponents and the sound transducers (201) can be arranged, in particular inserted from the front, in the at least one mounting frame (100).

In accordance with Huygens' principle, directional sound wave fronts can be composed of elementary waves from a large number of individual sound transducers. The alignment of the sound wave front can be determined by mechanically offsetting the individual sound transducers relative to each other and/or by electronically delaying the control signal.

Mechanical solutions for directional sound radiation have been widely used for many years in the form of curved line arrays, which are suspended above the stage at events. Electronic solutions for directional sound radiation using straight sound lines have also been on the market for more than a decade. Mathematical methods are used to control the timing and amplitude of each individual sound transducer so that the desired directivity of the emitted wavefront is achieved through the superposition of the elementary waves of the individual sound transducers in the elevation plane. However, the control options for such loudspeaker arrays are limited to this elevation plane. In the azimuth plane, the radiation characteristics of the array continue to be determined by the alignment of the individual sound transducer units.

Two-dimensional, electronically controllable sound transducer surfaces have also been available for several years. Sound wave fronts can be directed very precisely toward the audience area from their front surface, both in the azimuth and elevation planes. Unwanted reflections that mask the signal content can thus be largely avoided, even in acoustically unfavorable environments. The sound transducer systems, in particular the sound transducer surfaces, can be used for beamforming of the wavefront, or they can be used to generate several directional wavefronts simultaneously, even with different signal content, according to the principle of wavefield synthesis.

However, the installation of such loudspeaker array surfaces usually proves difficult. Precise alignment of the wavefronts down to the fundamental frequency range is only possible with sound transducer arrangements that are larger than the wavelength of the emitted audio signal. Correspondingly large surfaces with diagonals of several meters are difficult to transport. They are therefore generally assembled from modules, as is known from WO 2015 036508A1 .

In practice, the installation of such modules is a challenge. They are actively designed because each sound transducer requires its own amplifier. With separate amplifier units, the cabling effort becomes too great, so the power amplifiers are integrated into the modules. These active modules are then relatively heavy, so stable mounting systems are required. In addition, the demands on the mechanical precision of the sound transducer surface are very high. The position of each individual sound transducer in the room must be known with millimeter precision to ensure exact alignment of the wavefront up to the high-frequency range.

In very high-quality fixed installations, such two-dimensional sound transducer surfaces are also used in rooms that are acoustically difficult to control. Because the wavefront can also be electronically aligned at an angle to the listener area in both room axes, a suitable, stable wall surface is often available for mounting.

However, the modules cannot yet be mounted directly on the wall because sufficient space must be left between them and the mounting wall for cabling. Since the modules are only wired after they have been mechanically mounted, this space must be large enough to allow access. Rear ventilation of the active amplifiers must also be ensured. Furthermore, direct mounting is not possible for service reasons. In the event of a defect, all modules up to the affected unit would have to be dismantled and then rewired. For this reason, it has been common practice to construct a sturdy frame to which the individual modules are attached, even when direct mounting on a wall would be more advantageous.

The object of the invention is therefore to describe a device for mounting a modular sound transducer system that can be mounted on a frame or directly on a flat wall, whereby all electronic components of each individual module must remain accessible and replaceable even after complete assembly without the need to dismantle other modules.

This task is solved by the subject matter of claim 1.

The mounting system is designed for modular, electronically controllable sound transducer systems, in particular sound transducer panels. The mounting system has at least one module frame in which at least one module insert can be arranged. In many cases, a large number of mounting frames will be used, in each of which several module inserts can be arranged.

The at least one mounting frame is arranged at a fixed location, e.g., on a rack, on a flat surface, or on a wall, where it can be aligned and wired.

The at least one module insert with electronic components and the sound transducers can be arranged in the at least one mounting frame, in particular by being inserted from the front.

In a first step, all mounting frames can be mounted in particular, so that even after the complete modular, two-dimensional, electronically controllable sound converter surface has been mounted, all electronic components of each individual module can be accessed and replaced, for example by removing the module inserts from the front, without having to dismantle any other modules.

In one embodiment, a plurality of module frames can be mechanically connected to each other to form a flat module arrangement, a vertical column arrangement, or a horizontal column arrangement. For this purpose, the module frames have sufficient mechanical stability.

Furthermore, it is possible that each mounting frame is coupled to a terminal device or that each mounting frame has a terminal device, wherein supply and/or signal lines can be connected to the terminal device, e.g. via plug connectors. In particular, it is possible for the terminal device to also have elements for signal selection according to the position of the mounting frame within the mounting frames connected to form an array. This means that the sound transducers of each mounting frame can be controlled separately, e.g. by separating the elements for signal selection from a serial signal, which are assigned to the position of the respective module insert in the array for controlling the individual sound transducers.

Since the fixed locations at which the mounting system is mounted are often not completely level, at least one adjustment element, in particular an adjustment screw, can be used to compensate for this.

In a further embodiment, it is possible to connect metal sheets welded into the at least one mounting frame to a sheet metal part bent out of a flat steel sheet of the at least one mounting frame.

For secure positioning of the at least one module insert in the mounting frame, it is advantageous if the insertion depth of the at least one module insert is limited by at least one guide element. In addition or as an alternative, at least one centering element can be used for this purpose, which in particular also has the function of a guide element, wherein the at least one centering element ensures the centering of the at least one module insert so that the module insert arranged (e.g., inserted) with a small gap to the at least one mounting frame can be positioned at a defined position in the mounting frame.

In one embodiment, amplifier devices are integrated in at least one module insert or in all module inserts, which are each combined with the associated sound transducers to form a removable unit. At least one amplifier device is thermally coupled to at least one heat sink, wherein the at least one heat sink is arranged on the rear side of the mounting frame. In particular, the at least one amplifier device can also be connected to the terminal via an electrical connection, in particular a contact in the area of a connecting element, for example a printed circuit board, as soon as the module insert is inserted into the mounting frame.

A central fastening screw, which can be covered by a removable cap, can also engage in a female thread of a connecting piece on the at least one mounting frame and thus mechanically connect the mounting frame and the respective module insert to each other. This facilitates repair work.

It is also possible for several mounting frames to be combined as pre-assembled clusters.

Embodiments are explained by way of example in connection with the figures. They show:

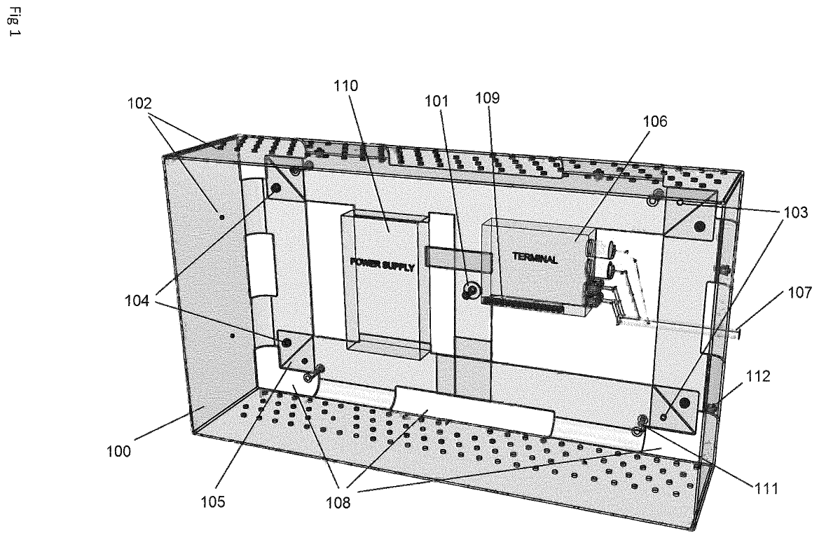

FIG. 1 an embodiment of a mounting frame;

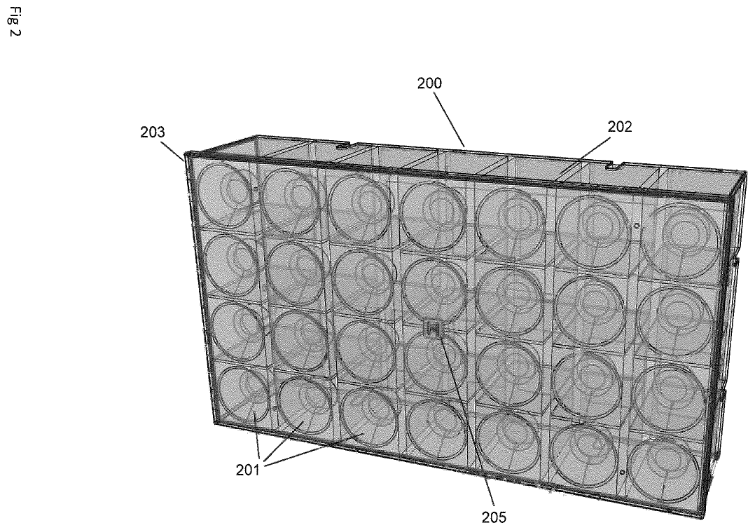

FIG. 2 an embodiment of a module insert;

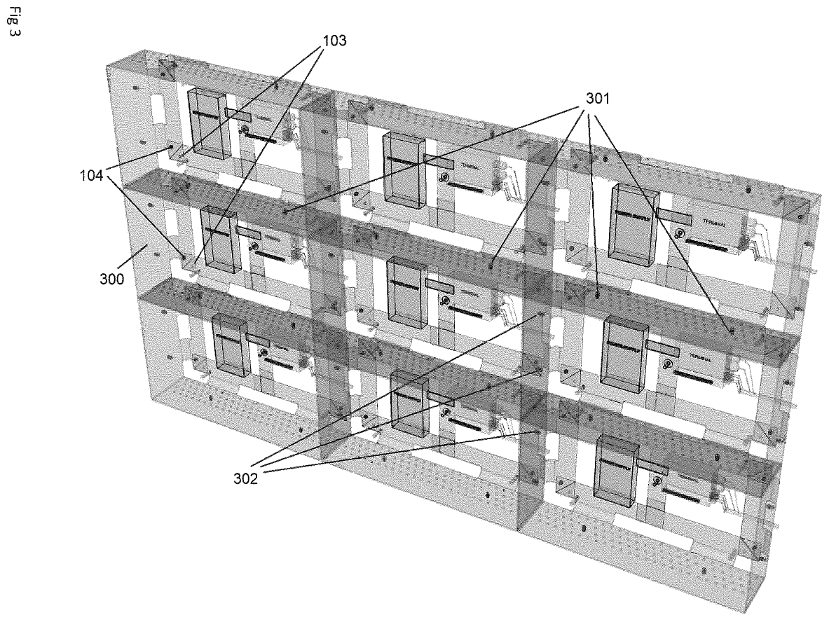

FIG. 3 a group of nine mounting frames (100);

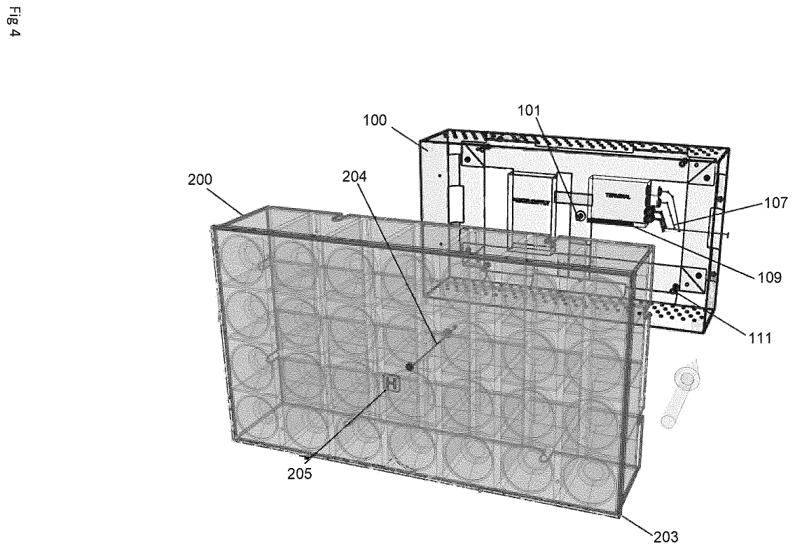

FIG. 4 shows the insertion of a module insert 200 into a mounting frame (100).

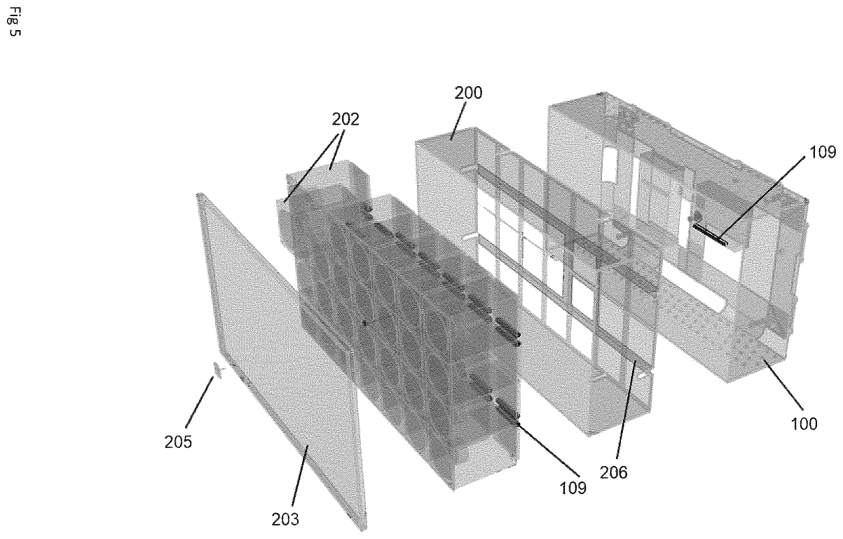

FIG. 5 Exploded view of components of an embodiment of the mounting system.

The following describes examples of embodiments for solving the problem. The mounting system comprises mounting frames 100 and module inserts 200. During assembly, all mounting frames 100 are first mounted, aligned, and wired at a fixed location (e.g., a wall). Then the module inserts 200 with electronic components, e.g., amplifier devices and the sound transducers 201, are inserted frontally into the mounting frames 100 and fastened. In principle, other mounting forms are also possible, such as inserting the module inserts 200 from above or below, or hanging the module inserts 200 in place.

In this way, even after the complete module wall has been assembled, the electronic components of the individual module inserts 200 are accessible and can be replaced from the front without having to dismantle any other module inserts 200.

In a first step, when constructing the sound transducer surface, the mounting frames 100 are assembled to the desired size and fastened to a wall, for example. Alternatively, a frame can still be used for fastening, to which the module frames 100 are suspended or fastened in another way. The module frames 100 are mechanically connected vertically and horizontally during assembly. Their mechanical stability also allows several rows to be suspended one above the other. Mounting on a wall is also possible. A single vertical column or a horizontal row can also be constructed from a row of modules.

A terminal device 106 can be installed in each mounting frame 100, to which the entire cabling can be connected from the open front side of the mounting frame 100 before the module inserts 200 are inserted.

The mounting frames 100 are designed so that there are sufficiently large openings on their rear side through which the corresponding cable connections 107 with their plug connectors can still be inserted even when the mounting frames 100 have already been attached to a wall. In addition, the rear openings of the mounting frames 100 ensure sufficient air circulation. On the front side, a plug connector or suitable piston contacts on the terminal device 106 ensure the subsequent electrical connection to the module inserts 200. The power supply unit 110 for supplying the module insert 200 can be optionally mounted in the module frame 100, or a central power supply can be provided via the cable connections 107.

After the module frames have been aligned and wired, the active module inserts 200 are inserted into the mounting frames 100 from the front. Their external dimensions are slightly smaller than the internal dimensions of the front part of the mounting frames 100 by a small gap width. A small gap width in the range of 1 mm is possible here. They are fixed in position, for example, by guide pins 111 or screw connections in the mounting frames 100. The screw connections can be covered by a front grille 204, which in turn has the outer dimensions of the mounting frames 100 minus the gap widths. It can be screwed to the module or attached to it magnetically. An exemplary embodiment of the invention is shown schematically in FIGS. 1 to 5. Other embodiments are possible.

FIG. 1 shows an example of a mounting frame 100. It is largely open at the rear. In the example solution, it is made of thicker sheet steel so that it is stable enough to screw and suspend larger assembly units consisting of module frames (100) and module inserts via connections in the outer surfaces of the module frames (100), which are located approximately in the plane of the center of gravity of the complete modules. Threaded nuts or other connecting pieces 112 are welded in place on the right and top for this purpose, and the mounting frames are then screwed or connected to each other through the holes 102 on the left and bottom.

Another mounting option is to screw the mounting frames 100 directly to a flat wall through the holes 103. Additional internal threads 104 allow unevenness in the wall to be compensated for with an adjusting screw. The rear wall of the mounting frame 100 can be made of sheet metal, whereby sections of the sheet metal can be cut (e.g., with a laser) and bent. The bent sections then stand perpendicular to the rear wall and can be used to hold components inside the mounting frame. In this area, connecting pieces 105 hold together the housing bent from the flat pattern (e.g., the rear wall). However, the mounting frame 100 can also be assembled from individual parts. The bent sheet metal can then be used as holding points for welded-in sheet metal.

A terminal device 106 is mounted in each mounting frame 100 to accommodate all cable connections 107. Openings 108 in the rear area of the mounting frames are large enough to allow cables with wired plugs to pass through. The cabling can also be set up using familiar network technology with Power over Ethernet (POE), optionally as a redundant network. All voltages and signals are forwarded from there to the module inserts 200 via piston contacts 109 or other plug connectors.

If the module inserts 200 are not supplied with operating voltage via a Power Over Ethernet connection, a power supply unit 110 is provided in the mounting frame 100. Alternatively, a central power supply unit that supplies all terminals 106 via cable connections 107 can be provided.

After all mounting frames 100 have been assembled, connected, and aligned to form an array 300 of connected mounting frames 100, the entire unit is wired 107 from the front. The insertion depth of the module units 200 is limited by spacers 111. They also center the inserted modules in the rear area, because a small gap must remain between the module frame and the module insert so that the module inserts 200 can be easily inserted into the mounting frames 100.

FIG. 2 shows such a module insert 200. The sound transducers 201, usually dynamic loudspeakers, are integrated into the front of the module insert. Acoustically, the individual sound transducers 201 should be separated by individual chambers 202 because their signals for beamforming or wave field synthesis applications are controlled separately in terms of time and amplitude. The respective integrated amplifiers with rear heat sinks and connectors 202 can be mounted on a contact unit, for example a printed circuit board, on the rear side of the chambers. They are connected to the terminal 106 via a contact unit, for example a printed circuit board with plug connectors, via the piston contacts or plug connectors 109 as soon as the module insert 200 is inserted into the mounting frame 100. After removing the front grille 203, individual loudspeaker units 202 can be easily replaced together with their amplifier and heat sink.

The units consisting of loudspeaker 202, integrated rear amplifier, heat sink, and plug connector can also contain components separated by frequency dividers for the low-midrange and high-frequency ranges, whereby several sound transducers can also be installed in each unit for the high-frequency range. These high-frequency sound transducers can also be driven with discrete signals if the corresponding number of separate amplifiers is installed in the mounting units.

Electronic components can be integrated into the contact unit, which provide the individual channels for controlling the individual sound transducers from a serial signal. The position of the individual sound transducers within the module insert 100 is determined by the mechanical design. However, the position of the module inserts 200 within the mounting frames 200 connected to the array 300 must be defined. One way of doing this is to provide corresponding switches or other adjustment options on the terminal device 106, which select the appropriate signal for the relevant position within the mounting frames 300 connected to the array.

The sound transducer membranes are protected by a front grille 203. It has the outer dimensions of the mounting frames and is connected to the module magnetically or with fastening screws. For safety reasons, if magnetic fastening is used, an additional front screw connection must be provided, or the front grille must be held in place by an additional central fastening screw 204.

Once the module insert 200 has been inserted into its mounting frame 100, the fastening screws are no longer accessible. In the example application, a central fastening screw 204 is therefore provided (see FIG. 4). It is accessible from the front behind a removable cap 205 and engages in the internal thread of the thread for the central fastening of the module insert 101 to the mounting frame 100.

FIG. 3 shows a group of nine mounting frames 100 which are mounted on a wall through the holes 103 or suspended from a crossbar by the threaded nuts 112. The maximum size of the module group is determined by the stability of the mounting frames 100 and the weight of the module inserts 200. Before the module inserts 200 are inserted from the front, the alignment of the flat surface must be checked and adjusted if necessary. In particular, if the module arrangement is used for the superposition of elementary waves according to the principle of wave field synthesis, millimeter-precise alignment is necessary, as otherwise frequency response dips in the overtone range will occur. Only after the cable connections 107 have been completely installed are the module inserts 200 inserted from the front and fixed in the module frame 100.

It is also possible to combine several mounting frames 100 as pre-assembled clusters. This simplifies the assembly process and alignment at the installation site because only the clusters need to be aligned precisely, not each individual mounting frame.

FIG. 4 shows the insertion of a module insert 200 into a mounting frame 100. In the example shown, the module insert 200 is only screwed in place with a stable, central fastening screw 204 with a thread for the central fastening of the module insert 200. The front grille 203 is connected to the module insert 200, preferably by means of screw connections on the side edges. The removable cap 205 is not yet placed on the screw head, so that the module can be pulled into the guide pieces and spacers 111 as far as it will go with the central fastening screw. This fixes the position of the module insert 200 precisely in the previously aligned mounting frame 100. The module insert 200 is supplied with all supply voltages and all signals for controlling the amplifiers via the piston contacts or plug connectors 109.

The levels and delay times for controlling the individual amplifiers are provided by an external processor unit.

FIG. 5 shows an exploded view of components in one embodiment of the mounting system. In FIG. 5, the components of the electrical connection between the assemblies are shown in a darker color. Piston contacts 109 connect during assembly of the assemblies via a through-plated printed circuit board 206 in the module insert 200. If necessary, electronic components can be mounted on this printed circuit board 206 to separate the signals from a data bus, which are then fed to the individual amplifiers in the loudspeaker housings 202. The illustration also shows that the assembly units consisting of loudspeaker housing, amplifier, and heat sink can be replaced individually from the front after removing the front grille 203 in the module frame 200. Other plug connectors can be used instead of the piston contacts.

### REFERENCE SIGN LIST

100 Mounting frame
101 Thread for central fastening of the module insert
102 Holes for mechanical connection of the mounting frames
103 Holes for screw connection to a flat wall
104 Adjustment element, internal thread with adjustment screw for compensating unevenness
105 Connection of the sheet metal parts bent from the flat pattern
106 Terminal device
107 Cabel connections
108 Openings in the rear area of the mounting frames
109 Piston contacts or plug connectors
110 Power supply unit in the mounting frame
111 Guide pieces and spacers
112 Connecting pieces on the mounting frame
200 Module insert
201 Sound transducer
202 Integrated amplifiers with rear heat sink and plug connectors
203 Front grille
204 Central fastening screw
205 Removable cap
206 Printed circuit board, circuit board
300 Mounting frames connected to the array
301 Vertical connections
302 Horizontal connections

1. A mounting system for a modular, electronically controllable sound transducer system, the mounting system comprising:
at least one mounting frame from among a plurality of mounting frames configured to be mounted at a fixed location, and
at least one module insert from among a plurality of module inserts,
wherein the at least one module insert is configured to be arranged within the at least one mounting frame and to be insertable into the at least one mounting frame from a front side of the at least one mounting frame,
at least one terminal device arranged in the at least one mounting frame and including a first electrical connection; and
at least one guide element arranged between the at least one mounting frame and the at least one module insert, the at least one guide element being configured to guide the at least one module insert during insertion from the front side of the at least one mounting frame such that a second electrical connection of the at least one module insert is aligned with and connected to the first electrical connection of the at least one terminal device.

2. The mounting system according to claim 1, wherein the plurality of mounting frames are mechanically connected to each other to form a flat module arrangement, a vertical column arrangement or a horizontal column arrangement.

3. The mounting system according to claim 1, wherein the at least one terminal device comprises a printed circuit board having a plurality of supply and signal lines, and
wherein the at least one module insert is coupled to corresponding supply and signal lines from among the plurality of supply and signal lines by connecting the first electrical connection and the second electrical connection.

4. The mounting system according to claim 3, wherein the at least one terminal device further comprises a plurality of signal selection elements configured to:
identify a position of the at least one mounting frame from among the plurality of mounting frames, and
extract the corresponding supply and signal lines that correspond to the position of the at least one mounting frame from among the plurality of supply and signal lines, and
couple the corresponding supply and signal lines to the first electrical connection of the terminal device.

5. The mounting system according to claim 1, wherein the at least one mounting frame is configured to be spaced apart from the fixed location by a gap between the at least one mounting frame and the fixed location,
wherein the gap provides sufficient room for cables with their connectors behind the plurality of mounting frames after installation to maintain adequate clearance to ensure cooling of the at least one module insert.

6. The mounting system according to claim 1, wherein the at least one mounting frame comprises at least one adjusting element configured to compensate for unevenness at the fixed location.

7. The mounting system according to claim 1, wherein the at least one mounting frame comprises a first plurality of sheet metal parts welded into the at least one mounting frame configured to connect a second plurality of sheet metal parts that are bent from a flat steel sheet forming part of the at least one mounting frame.

8. The mounting system according to claim 1, wherein the at least one guide element is arranged between the at least one mounting frame and the at least one module insert to limit an insertion depth of the at least one module insert.

9. The mounting system according to claim 1, wherein the at least one terminal device comprises at least one centering element configured to position the at least one module insert at a defined position in the at least one mounting frame while maintaining a gap between the at least one module insert and the at least one mounting frame.

10. The mounting system according to claim 1, wherein the at least one module insert comprises a plurality of reinforcing devices that couple to a plurality of sound transducers to form a removable unit.

11. The mounting system according to claim 10, wherein the at least one mounting frame comprises at least one amplifier device thermally coupled to at least one heat sink that is arranged on a rear side of the at least one mounting frame.

12. The mounting system according to claim 11, wherein the at least one amplifier device is connected to the at least one terminal device via a third electrical connection, and wherein the at least one amplifier device is connected the at least one module insert when the at least one module insert is inserted into the at least one mounting frame

13. The mounting system claim 1, wherein the at least one module insert comprises a central fastening screw, and
wherein the at least one mounting frame comprises a female thread of a connecting piece to engage the central fastening screw to mechanically connect the at least one mounting frame and the at least one module insert.

14. The mounting system according to claim 1, wherein the plurality of mounting frames are combined as a pre-assembled cluster.

15. A method of mounting a modular, electronically controllable sound transducer system, the method comprising:
mounting at least one mounting frame at a fixed location;
providing at least one module insert configured to be arranged within the least one mounting frame and insertable from a front side of the at least one mounting frame;
providing at least one terminal device arranged in the at least one mounting frame and including a first electrical connection;
arranging at least one guide element between the at least one mounting frame and the at least one module insert;
inserting the at least one module insert into the at least one mounting frame from the front side to engage the at least one guide element to guide the at least one module insert during insertion such that a second electrical connection of the at least one module insert is aligned with and connected to the first electrical connection of the at least one terminal device.

16. The method of claim 15, further comprising coupling the at least one module insert to corresponding supply and signal lines from among a plurality of supply and signal lines on a printed circuit board by connecting the first electrical connection and the second electrical connection.

17. The method of claim 16, further comprising:
identifying the position of the mounting frame from among a plurality of mounting frames using a plurality of signal selection elements in the at least one terminal device;
extracting the corresponding supply and signal lines that correspond to the position of the at least one mounting frame from among the plurality of supply and signal lines, and coupling the corresponding supply and signal lines to the first electrical connection of the terminal device.

18. The method of claim 15, further comprising mounting the at least one mounting frame at a sufficient distance from the fixed location to provide a gap, the gap being configured to allow cable and connector arrangement and to ensure cooling of components in the at least one module insert.

19. The method of claim 15, further comprising limiting the insertion depth of the at least one module insert using at least one guide element arranged between the at least one mounting frame and the at least one module insert.

20. The method of claim 15, further comprising:
connecting an amplifier device to the at least one terminal device via a third electrical connection; and
connecting the at least one module insert to the amplifier device upon insertion of the at least one module insert into the mounting frame.
